(19) United States
(12) Patent Application Publication
(10) Pub. No.: US 2008/0213069 A1
(43) Pub. Date: Sep. 4, 2008

(54) APPARATUS FOR FABRICATING SEMICONDUCTOR DEVICES AND METHODS OF FABRICATING SEMICONDUCTOR DEVICES USING THE SAME

(75) Inventors: Chul-Gi Song, Gyeonggi-do (KR); Deok-yong Kim, Gyeonggi-do (KR); Yong-Chul Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/028,993

(22) Filed: Feb. 11, 2008

(30) Foreign Application Priority Data
Feb. 16, 2007 (KR) 10-2007-0016452

(51) Int. Cl. H01L 21/67

(52) U.S. Cl. 414/222.01; 29/25.01; 901/50

(57) ABSTRACT

An apparatus for fabricating semiconductor devices is provided. The apparatus includes a process equipment in which a process is performed and a transfer system attached to the process equipment to supply a substrate to the process equipment. The transfer system includes a transfer robot for moving the substrate and a light supplier for supplying ultraviolet rays to the substrate. Methods of fabricating the semiconductor devices using the apparatus are also provided.

### CROSS-REFERENCE TO RELATED APPLICATION

This U.S. non-provisional patent application claims priority under 35 U.S.C § 119 of Korean Patent Application No. 10-2007-0016452, filed on Feb. 16, 2007, the disclosure of which is hereby incorporated by reference in its entirety.

### FIELD AND BACKGROUND

The present invention relates to apparatus for fabricating semiconductor devices and methods of fabricating semiconductor devices using the same.

In general, semiconductor devices may be fabricated using unit processes such as, for example, a chemical vapor deposition (CVD) process, a photolithography process or an etching process. The unit processes may be performed using several process gases such as a chlorine (Cl) gas, hydrogen bromide (HBr) gas, carbon hydrogen tri-fluoride (CHF₃) gas or carbon dihydrogen difluoride (CH₂F₂) gas. The process gases may react with moisture in the air to generate contaminants such as liquid condensed materials on a semiconductor wafer. (See, FIG. 1.) The liquid condensed materials may cause some defects in a semiconductor device fabricated on the semiconductor wafer. For example, when the liquid condensed materials cover contact holes, the contact resistance between two conductors connected through the contact hole may abruptly increase to cause a malfunction of the semiconductor device. That is, the liquid condensed materials may lead to degradation of reliability of the semiconductor device and reduction of yield of the semiconductor device.

A cleaning process may be required to remove the liquid condensed materials. The cleaning process may comprise a quick dump rinse (QDR) process which cleans surfaces of the semiconductor wafers using a large amount of de-ionized (DI) water. However, the QDR process may cause increase of process time and may result in other contamination due to the DI water.

### SUMMARY OF THE INVENTION

Exemplary embodiments of the present invention are directed to apparatus for fabricating semiconductor devices and methods of fabricating semiconductor devices using the same. In an exemplary embodiment, the apparatus may comprise a process equipment in which a process may be performed and a transfer system attached to the process equipment to supply a substrate into the process equipment. The transfer system may include a transfer robot for moving the substrate and a light supplier for supplying ultraviolet rays to the substrate.

In some embodiments, the light supplier may comprise a light emitter for generating the ultraviolet rays and a light concentrator for condensing the ultraviolet rays. The light concentrator may radiate the condensed ultraviolet rays onto the substrate.

In other embodiments, the transfer system may further comprise a load port on which a vessel accommodating the substrate is placed and a frame disposed between the load port and the process equipment. The transfer robot may be disposed in the frame. The transfer system may further comprise a supporter connected to the frame to position the light supplier at a desired location in the frame. The supporter may be moved upwardly and downwardly.

In yet other embodiments, the transfer system may further comprise an exhausting portion through which contaminants separated from the substrate by the ultraviolet rays may be vented out. The exhausting portion may be disposed below the frame.

In still other embodiments, the transfer system may further comprise a controller which controls the transfer robot and the light supplier.

In another exemplary embodiment, the method of manufacturing the semiconductor device may be performed using the semiconductor fabrication apparatus. The method may comprise the steps of (a) loading a substrate into a transfer system of the semiconductor fabrication apparatus, (b) transferring the substrate in the transfer system into a process equipment of the semiconductor fabrication apparatus using a transfer robot of the transfer system, (c) applying a unit process to the substrate in the process equipment, and (d) transferring the substrate in the process equipment to an outside region of the transfer system via the transfer system using the transfer robot. At least one of the steps (b) and (d) may include supplying ultraviolet rays to the substrate using a light supplier of the transfer system, wherein the ultraviolet rays remove contaminants on the substrate.

In some embodiments, the contaminants may comprise liquid condensed materials. The liquid condensed materials may be formed by a process gas used in the unit process, for example, the process gas may comprise chlorine gas.

In other embodiments, the transfer robot and the light supplier may be operated by a controller of the transfer system. Operation of the light supplier may be subject to operation of the transfer robot.

In still another exemplary embodiment, the method comprises transferring a substrate and supplying ultraviolet rays to the substrate while the substrate is transferred, wherein the ultraviolet rays remove liquid contaminants on the substrate.

In some embodiments, the method may further comprise applying a unit process to the substrate before or after the substrate is transferred. The liquid contaminants may be formed by a process gas used in the unit process.

### BRIEF DESCRIPTION OF THE DRAWINGS

FIG. 1 illustrates some contaminants formed on a semiconductor wafer during fabrication of a semiconductor device using a conventional apparatus.

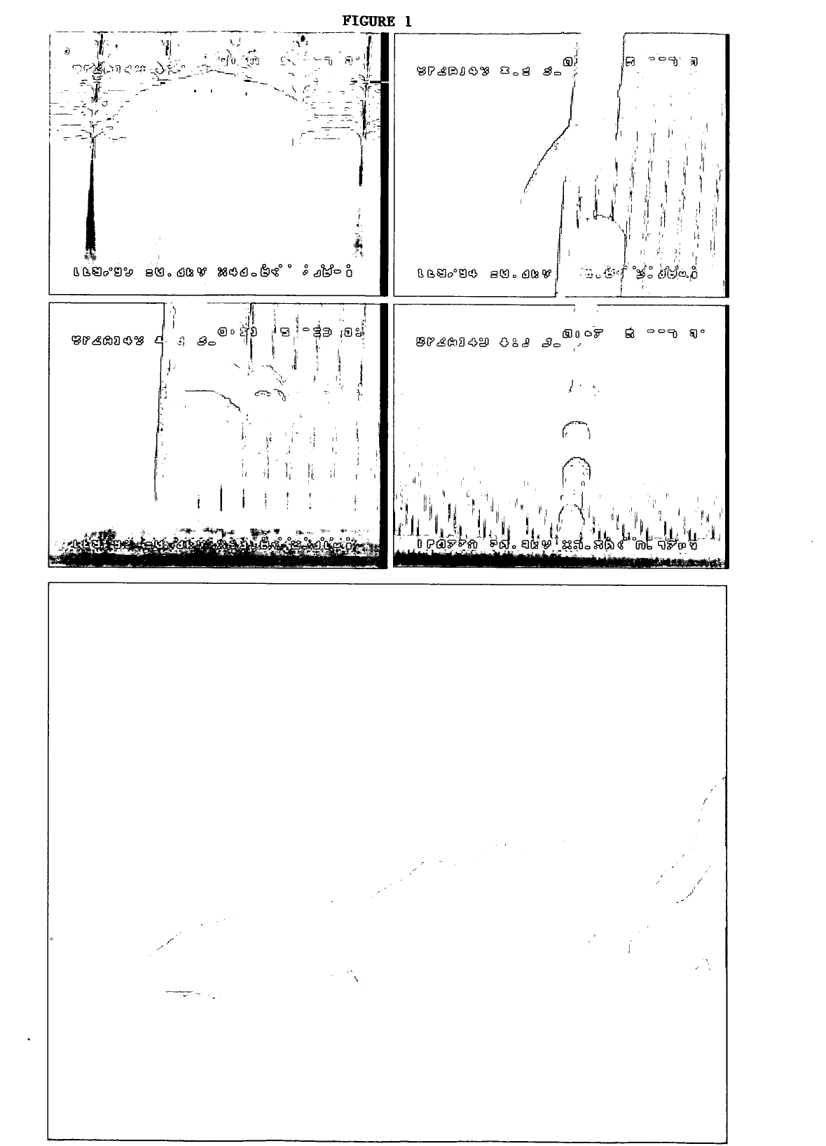

FIG. 2 is a schematic view illustrating an apparatus according to an embodiment of the present invention.

FIG. 3 is a schematic view of the apparatus of FIG. 2 that illustrates methods of fabricating a semiconductor device, according to embodiments of the present invention.

FIG. 4 is a process flow chart illustrating methods of fabricating a semiconductor device using an apparatus according to an embodiment of the present invention.

FIG. 5 illustrates surfaces of semiconductor wafers which are processed using an apparatus according to an embodiment of the present invention.

### DETAILED DESCRIPTION OF PREFERRED EMBODIMENTS

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, and may not be limited to silicon. In addition, the substrate described hereinafter may be one in which regions, conductive layers, insulation layers, their patterns, and/or junctions are formed.

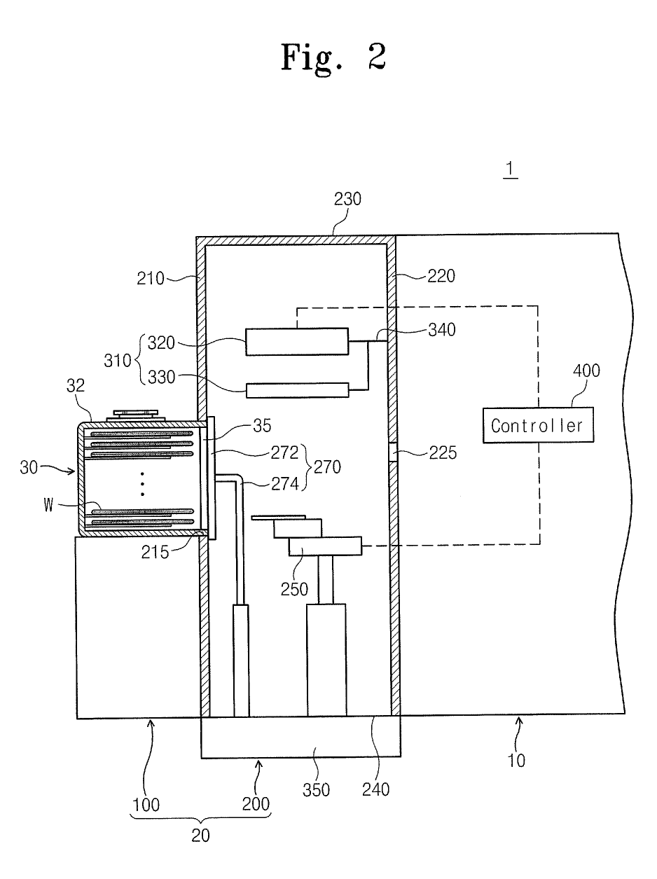

FIG. 2 is a schematic view illustrating an apparatus according to an embodiment of the present invention. The apparatus may be used in fabrication of semiconductor devices.

Referring to FIG. 2, the apparatus 1 may include a process equipment 10 and a transfer system 20 installed at a front end of the process equipment 10. The process equipment 10 may include at least one load lock chamber and at least one process chamber. The process chamber may be a chamber in which a unit process such as chemical vapor deposition process, a photolithography process or an etching process or the like is performed.

The transfer system 20 may include a load port 100 on which a vessel 30 is placed and a frame 200 which provides an empty space. The atmosphere in the frame 200 may be maintained at a high clean level. The transfer system 20 may be an equipment front end module (EFEM).

The load port 100 may be disposed at a front end of the frame 200, and the load port 100 may have a flat top surface. The load port 100 may comprise a single sub-load port or a plurality of sub-load ports. The vessel 30 to be put on the load port 100 may have a body 32 providing a space and a door 35 for separating the space in the body 32 from an outside region of the body 32. At least one wafer W or other substrate may be loaded into the body 32. The body 32 may have a sidewall, and a plurality of slots may be formed at an inner surface of the sidewall of the body 32. The wafers loaded in the vessel 30 may be inserted into the slots. The space in the vessel 30 may be sealed by the door 35 to prevent external air from being introduced into the vessel 30. The vessel 30 may be a front open unified pod (FOUP).

The frame 200 may be located between the process equipment 10 and the load port 100. The frame 200 may have a hexahedral shape. One or more transfer robots 250 may be disposed in the frame 200, and the transfer robots 250 may move the wafers in the vessel 30 into the process equipment 10 or vice versa. The frame may have a front wall 210 which is adjacent to the load port 100, and the front wall 210 may have an opening 215 through which the wafers are transferred. A door controller 270 may be installed in the frame 200, and the door controller 270 moves the door 35 to close or open the opening 215. When the opening 215 is closed by the door 35, the space in the vessel 30 may be sealed. The door controller 270 may include a door holder 272 and an arm 274. The door holder 272 may be connected to the door 35, and the arm 274 may move the door holder 272 upwardly or downwardly. Accordingly, if the arm 274 is moved, the opening 215 may be opened or closed.

The frame 200 may further include a rear wall 220 which is adjacent to the process equipment 10, and the rear wall 220 may have an opening 225 through which the wafers are transferred. The frame 200 may also have a top plate 230, and a fan filter unit (not shown) may be installed at the top plate 230. The fan filter unit may operate to maintain the atmosphere in the frame 200 at a high clean level. The fan filter unit may include a fan and a filter installed under the fan. The fan may be rotated by a motor. The outside air of the frame 200 may be introduced into the frame 200 when the fan is rotated, and the filter may purify the air which is introduced into the frame 200. The frame 200 may also include a bottom plate 240, and the bottom plate 240 may have one or more vents. The purified air in the frame 200 may be exhausted through the vents.

A light supplier 310 may be disposed over the transfer robot 250 which is located in the frame 200. The light supplier 310 may include a light emitter 320 generating ultraviolet (UV) rays and a light concentrator 330 condensing the UV rays generated from the light emitter 320. The UV rays generated from the light emitter 320 may be irradiated onto the wafer W, which is transferred by the robot 250, through the light concentrator 330. The UV rays may remove contaminants (e.g., liquid condensed materials) formed on the wafer W. The light emitter 320 may comprise a UV lamp, and the light concentrator 330 may comprise a condensing lens through which the UV rays penetrate. The light supplier 310 may be attached to the frame 200 by a supporter 340. The supporter 340 may be moved upwardly and downwardly to position the light supplier 310 at a desired location in the frame 200. An exhausting portion 350 may be disposed below the frame 200, and the contaminants detached from the wafer W by the UV rays may be vented out through the exhausting portion 350.

The transfer system 20 may further include a controller 400 which controls the light supplier 310 and the transfer robot 250. The controller 400 may operate the light emitter 320 while the transfer robot 250 is moved. That is, the light emitter 320 may be operated by the controller 400 to generate the UV rays only when the wafer W is transferred by the robot 250. Thus, light emitter 320 may not generate the UV rays when the robot 250 does not operate. As a result, power consumption of the transfer system 20 may be decreased.

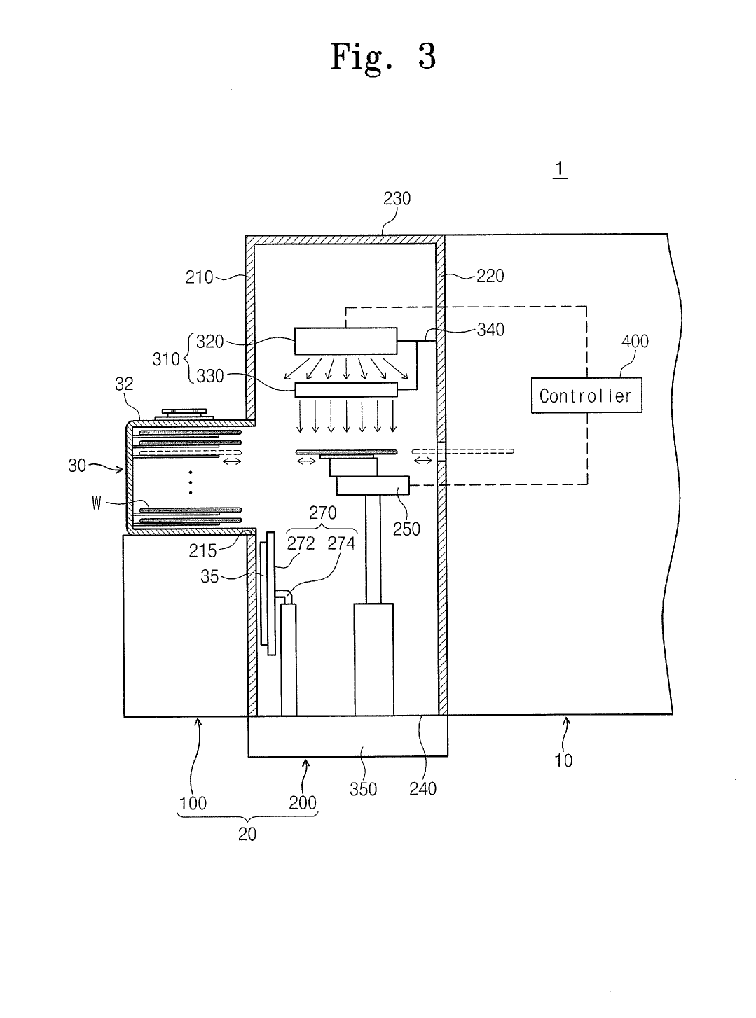

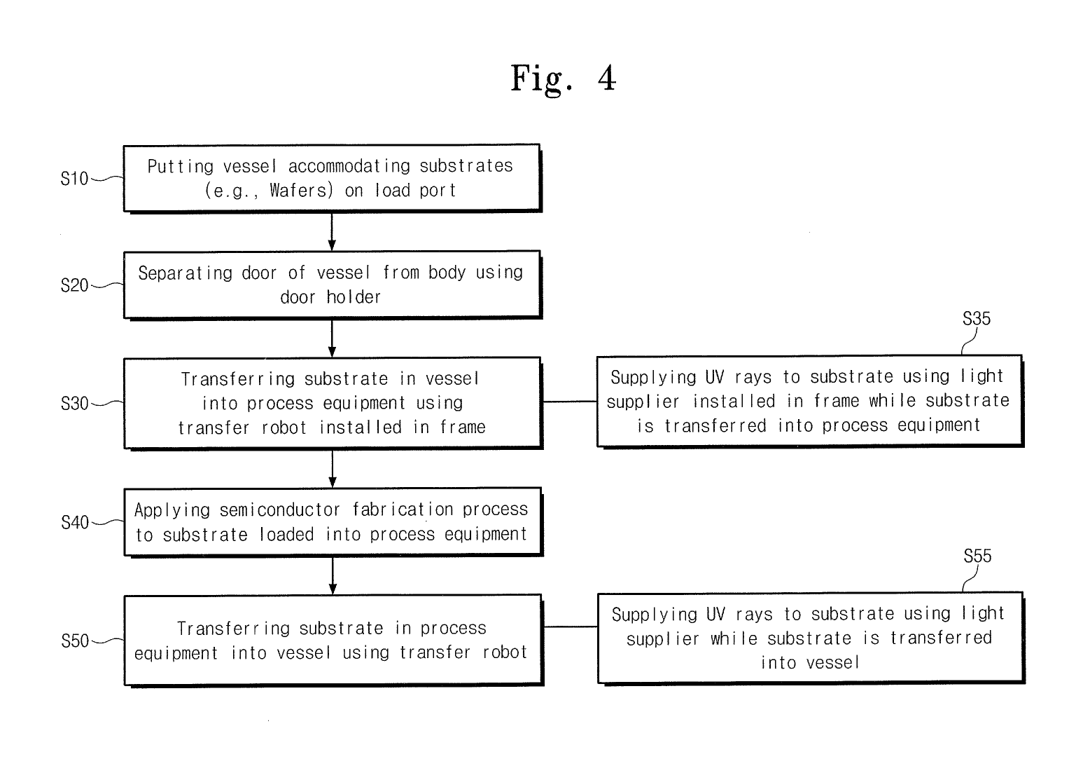

Now, methods of fabricating a semiconductor device will be described with reference to FIGS. 3 and 4. FIG. 3 is a schematic view of an apparatus 1 used in fabrication of a semiconductor device, and FIG. 4 is a process flow chart illustrating methods of fabricating a semiconductor device using the apparatus shown in FIG. 3.

Referring to FIGS. 3 and 4, a vessel 30 accommodating a plurality of wafers W or other substrates may be put on a load port 100 (step S10 of FIG. 4). The vessel 30 may be put on the load port 100 by a transfer unit (not shown). The transfer unit may comprise an overhead transfer unit, an overhead conveyer unit or an automatic guided vehicle.

The vessel 30 may include a body 32 providing a space and a door 35 for sealing the space in the body 32. The door 35 may be separated from the body 32 to open the vessel 30 (step S20 of FIG. 4). The door 35 may be moved by a door holder 272, and the door holder 272 physically connected to the door 35 may be moved downwardly by an arm 274. In this case, the vessel 30 may be opened as described above. As a result, the space in the vessel 30 is spatially connected to the outside region of the vessel 30 through an opening 215. A frame 200 may be disposed at one side of the load port 100, and a door controller 270 including the door holder 272 and the arm 274 may be installed in the frame 200. Thus, if the vessel 30 is opened, the space in the vessel 30 may be spatially connected to a space in the frame 200 through the opening 215.

If the vessel 30 is opened, a transfer robot 250 installed in the frame 200 may be operated to transfer one of the wafers W in the vessel 30 into a process equipment 10 which may be disposed at one side of the frame 200 (step S30 of FIG. 4). While the wafer W is transferred by the robot 250, a light supplier 310 installed in the frame 200 may operate to generate UV rays and the UV rays may be irradiated onto the wafer W (step S35 of FIG. 4). The light supplier 310 may comprise a light emitter 320 (e.g., a UV lamp) generating the UV rays and a light concentrator 330 supplying or condensing the UV rays. The UV rays from the light emitter 320 may pass through the light concentrator 330, and the condensed UV rays may reach the wafer W which may be transferred by the robot 250. The supplied or condensed UV rays may remove contaminants (e.g., liquid condensed materials) formed on the wafer W. The contaminants may comprise a variety of particles such as the liquid condensed materials formed in various unit processes before the wafer W is transferred into the frame 200. The unit process may include at least one of a chemical vapor deposition (CVD) process, a photolithography process or an etch process, and the liquid condensed materials may contain reactants of process gases and de-ionized water which are used in the unit processes. The process gas may comprise at least one of chlorine (Cl) gas, hydrogen bromide (HBr) gas, carbon hydrogen tri-fluoride (CHF₃) gas or carbon di-hydrogen di-fluoride (CH₂F₂) gas. The contaminants removed from the wafer W by the UV rays may be vented out by an exhausting portion 350 which is disposed under the frame 200.

The transfer robot 250 and the light supplier 310 may be operated by a controller 400. For example, the controller 400 may operate the light emitter 320 of the light supplier 310 only when the transfer robot 250 operates. The number and size of the liquid condensed materials on the wafer W may depend on conditions of the unit processes performed before the wafer W is transferred into the frame 200, and the controller 400 may control the moving speed of the transfer robot 250 and the intensity of the UV rays according to the number and size of the liquid condensed materials. Thus, power consumption of an apparatus including the light supplier 310 may be minimized by employing the controller 400.

The wafer W loaded into the process equipment 10 may be subjected to a semiconductor fabrication process (step S40 of FIG. 4). The semiconductor fabrication process may also comprise a unit process such as a chemical vapor deposition (CVD) process, a photolithography process or an etch process, the selection of which will be within the skill of one in the art. The unit process may be performed in the process equipment 10. The unit process in the process equipment 10 may also be performed using at least one of the process gases including chlorine (Cl) gas, hydrogen bromide (HBr) gas, carbon hydrogen tri-fluoride (CHF₃) gas or carbon di-hydrogen di-fluoride (CH₂F₂) gas. Thus, when the unit process is performed in the process equipment 10, the process gas may react with moisture in the process equipment 10 to form new liquid condensed materials on the wafer W.

The wafer W in the process equipment 10 may be transferred into the vessel 30 by the robot 250 after completion of the unit process in the process equipment 10 (step S50 of FIG. 4). The light supplier 310 may operate to radiate UV rays onto the wafer W while the wafer W in the process equipment 10 is transferred into the vessel 30 (step S55 of FIG. 4). The UV rays may be generated by the light emitter 320 of the light supplier 310, and the UV rays from the light emitter 320 may be irradiated onto the wafer W through the light concentrator 330. The UV rays may remove the new liquid condensed materials which are formed on the wafer W during the unit process performed in the process equipment 10. The new liquid condensed materials detached from the wafer W may be vented out by the exhausting portion 350 which is disposed under the frame 200.

The transfer robot 250 and the light supplier 310 may be operated by the controller 400, as described above. Thus, the controller 400 may operate the light emitter 320 of the light supplier 310 only when the transfer robot 250 operates. Further, the controller 400 may control the moving speed of the transfer robot 250 and the intensity of the UV rays according to the number and size of the new liquid condensed materials.

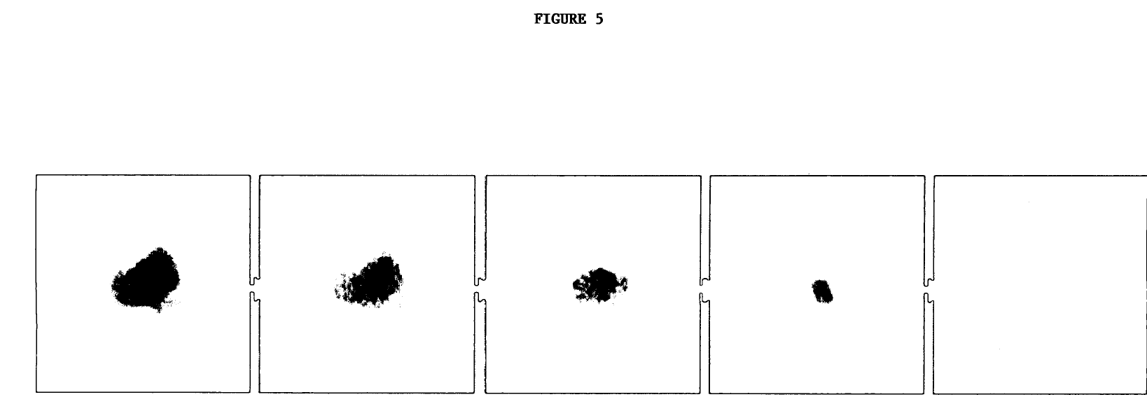

FIG. 5 shows a surface of a semiconductor wafer which was processed using an apparatus according to an embodiment of the present invention. As can be seen from FIG. 5, the size of the contaminant formed on the wafer W has been gradually reduced and finally removed as the number of processes applied to the wafer W using an apparatus according to embodiments of the present invention increases.

As discussed above, UV rays may be irradiated onto a wafer while the wafer is transferred by a robot, and the UV rays remove contaminants such as liquid condensing materials on the wafer. Thus, the contaminants on the wafer may be removed even without use of an additional cleaning process.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. An apparatus used in fabrication of a semiconductor device, the apparatus comprising:
a process equipment in which a process is performed; and
a transfer system attached to the process equipment to supply a substrate to the process equipment,
wherein the transfer system comprises:
a transfer robot for moving the substrate and
a light supplier for supplying ultraviolet rays to the substrate.

2. The apparatus as set forth in claim 1, wherein the light supplier comprises:
a light emitter for generating the ultraviolet rays and
a light concentrator for condensing the ultraviolet rays and radiating the condensed ultraviolet rays onto the substrate.

3. The apparatus as set forth in claim 1, wherein the transfer system further comprises:
a load port on which a vessel is put, the vessel accommodating the substrate and
a frame disposed between the load port and the process equipment,
wherein the transfer robot is disposed in the frame.

4. The apparatus as set forth in claim 3, wherein the transfer system further comprises a supporter connected to the frame to position the light supplier at a desired location in the frame.

5. The apparatus as set forth in claim 4, wherein the supporter is movable upwardly and downwardly.

6. The apparatus as set forth in claim 3, wherein the transfer system further comprises an exhausting portion through which contaminants removed from the substrate by the ultraviolet rays are vented out.

7. The apparatus as set forth in claim 6, wherein the exhausting portion is disposed below the frame.

8. The apparatus as set forth in claim 1, wherein the transfer system further comprises a controller which controls the transfer robot and the light supplier.

9. A method of manufacturing a semiconductor device using a semiconductor fabrication apparatus, the method comprising the steps of:
(a) loading a substrate into a transfer system of the semiconductor fabrication apparatus;
(b) transferring the substrate into a process equipment of the semiconductor fabrication apparatus, using a transfer robot of the transfer system;
(c) applying a unit process to the substrate in the process equipment; and
(d) transferring the substrate in the process equipment to an outside region of the transfer system via the transfer system using the transfer robot,
wherein at least one of the steps (b) and (d) includes supplying ultraviolet rays to the substrate using a light supplier of the transfer system, and wherein the ultraviolet rays remove contaminants on the substrate.

10. The method as set forth in claim 9, wherein the contaminants comprise liquid condensed materials.

11. The method as set forth in claim 10, wherein the liquid condensed materials are formed by a process gas used in the unit process.

12. The method as set forth in claim 11, wherein the process gas comprises a chlorine gas.

13. The method as set forth in claim 9, wherein the transfer robot and the light supplier are operated by a controller of the transfer system, and wherein operation of the light supplier only occurs during operation of the transfer robot.

14. A method of manufacturing a semiconductor device, comprising:
transferring a substrate; and
supplying ultraviolet rays to the substrate while the substrate is transferred,
wherein the ultraviolet rays remove liquid contaminants on the substrate.

15. The method as set forth in claim 14, further comprising applying a unit process to the substrate before or after the substrate is transferred.

16. The method as set forth in claim 15, wherein the liquid contaminants are formed by a process gas used in the unit process.
